(19) United States
(12) Patent Application Publication
(10) Pub. No.: US 2009/0308380 A1
(43) Pub. Date: Dec. 17, 2009

(54) Telescoping Devices

(75) Inventor: Samuel Palmer, Arlington, MA (US)

Correspondence Address: FISH & RICHARDSON PC, P.O. BOX 1022, MINNEAPOLIS, MN, 55440-1022, US

(73) Assignee: Konarka Technologies, Inc., Lowell, MA (US)

(21) Appl. No.: 12/434,969

(22) Filed: May 4, 2009

Related U.S. Application Data
(60) Provisional application No. 61/061,791, filed on Jun. 16, 2008.

(51) Int. Cl. F24J 2/46

(52) U.S. Cl. 126/704

(57) ABSTRACT

Telescoping devices, as well as related components, systems, and methods, are disclosed.

### CROSS REFERENCE TO RELATED APPLICATION

Pursuant to 35 U.S.C. §119(e), this application claims priority to U.S. Provisional Application Ser. No. 61/061,791, filed Jun. 16, 2008, the contents of which are hereby incorporated by reference.

### TECHNICAL FIELD

This disclosure relates to telescoping devices, as well as related components, systems, and methods.

### BACKGROUND

Transportable panels including photovoltaic cells, which can convert energy in the form of light into energy in the form of electricity at any suitable location, are known in the art. However, it remains desirable to develop devices to protect the transportable panels from dust and mechanical damage or to conveniently store the transportable panels during transportation and storage.

### SUMMARY

This disclosure relates to telescoping devices, as well as related components, systems, and methods.

In one aspect, this disclosure features a device that includes a first tube having a first slot and an inner diameter, a first panel of photovoltaic cells in the first tube, a second tube having a second slot and an outer diameter, and a second panel of photovoltaic cells in the second tube. At least a portion of the first panel and at least a portion of the second panel are configured to be reversibly pulled in or out of the first and second tubes through the first and second slots, respectively. The outer diameter of the second tube is smaller than the inner diameter of the first tube. At least a portion of the second tube is inserted in the first tube.

In another aspect, this disclosure features a device that includes a telescoping tube having a slot and a panel of photovoltaic cells in the telescoping tube. At least a portion of the panel is configured to be reversibly pulled in or out of the telescoping tube through the slot.

In yet another aspect, this disclosure features a device (e.g., a telescoping device) that includes a telescoping article (e.g., a telescoping tube) and at least one photovoltaic cell in the telescoping article.

Implementations can include one or more of the following features.

The entire first panel can be configured to be reversibly pulled in or out of the first tube through the first slot and the entire second panel can be configured to be reversibly pulled in or out of the second tube through the second slot.

The device can further include a first member attached to the first panel and a second member attached to the second panel. The first member can be configured to prevent separation of the first panel from the first tube when the first panel is pulled out of the first tube through the first slot. The second member can be configured to prevent separation of the second panel from the second tube when the second panel is pulled out of the second tube through the second slot. The first member can be a first mandrel concentrically disposed in the first tube and the second member can be a second mandrel concentrically disposed in the second tube. The first panel can be rolled onto the first mandrel when the first panel is disposed in the first tube and the second panel can be rolled onto the second mandrel when the second panel is disposed in the second tube.

The first tube can further include a first opening of the first tube, a second opening of the first tube, and a cap of the first tube. In this implementation, the second tube can further include a first opening of the second tube, a second opening of the second tube, and a cap of the second tube. The cap of the first tube can be configured to cover the first opening of the first tube and the cap of the second tube can be configured to cover the second opening of the second tube. The first opening of the second tube can be inserted into the first tube through the second opening of the first tube.

The second tube can be configured to be completely inserted into the first tube.

The first panel can be configured to be attached to the second panel when the first and second panels are respectively pulled out of the first and the second slots.

The first tube can have an outer diameter and a length. The ratio between the outer diameter of the first tube and the length of the first tube can be from about 1:2 to about 1:4. The first tube can have an outer diameter of about 2.75 inches and a length of about 8.38 inches.

The second tube can be movable relative to the first tube.

The first or second tube can include plastic or metal.

The first or second panel can include photovoltaic cells having a photoactive layer that includes an organic electron donor material and an organic electron acceptor material.

The organic electron donor material can include a polymer selected from the group consisting of polythiophenes, polyanilines, polyvinylcarbazoles, polyphenylenes, polyphenylvinylenes, polysilanes, polythienylenevinylenes, polyisothianaphthanenes, polycyclopentadithiophenes, polysilacyclopentadithiophenes, polycyclopentadithiazoles, polythiazolothiazoles, polythiazoles, polybenzothiadiazoles, poly(thiophene oxide)s, poly(cyclopentadithiophene oxide)s, polythiadiazoloquinoxaline, polybenzoisothiazole, polybenzothiazole, polythienothiophene, poly(thienothiophene oxide), polydithienothiophene, poly(dithienothiophene oxide)s, polytetrahydroisoindoles, and copolymers thereof. The organic electron donor material can include a polymer selected from the group consisting of polythiophenes, polycyclopentadithiophenes, and copolymers thereof. In some implementations, the organic electron donor material includes poly(3-hexylthiophene) or poly(cyclopentadithiophene-co-benzothiadiazole).

The organic electron acceptor material can include a material selected from the group consisting of fullerenes, oxadiazoles, discotic liquid crystals, carbon nanorods, polymers containing CN groups, polymers containing CF3 groups, and combinations thereof. The organic electron acceptor material can include a substituted fullerene. The substituted fullerene can include C61-phenyl-butyric acid methyl ester (C61-PCBM) or C71-phenyl-butyric acid methyl ester (C71-PCBM).

The entire panel can be configured to be reversibly pulled in or out of the tube through the slot.

The device can further include a member attached to the panel of photovoltaic cells, the member being configured to prevent separation of the panel from the telescoping tube when the at least a portion of the panel is pulled out of the telescoping tube through the slot. The member can be a mandrel concentrically disposed in the telescoping tube. The panel can be rolled onto the mandrel when the panel is disposed in the telescoping tube.

The telescoping tube can further include a first opening, a second opening, a first cap configured to cover the first opening, and a second cap configured to cover the second opening.

The at least a portion of the panel can be configured to be split into at least two sub-panels when it is pulled out of the telescoping tube through the slot.

The telescoping tube can have a first length at a collapsed state and a second length at an extended state, the second length being larger than the first length. The second length can be at least about twice (e.g., at least about three times) as large as the first length. The telescoping tube can have an outer diameter, the ratio between the outer diameter and the first length being from about 1:2 to about 1:4. In some implementations, the telescoping tube has an outer diameter of about 2.75 inches and a first length of about 8.38 inches.

The telescoping tube can include plastic or metal.

The panel can include photovoltaic cells having a photoactive layer that includes an organic electron donor material and an organic electron acceptor material.

The at least one photovoltaic cell can be movable relative to the telescoping article. The at least one photovoltaic cell can be part of a panel that includes a plurality of photovoltaic cells. The at least one photovoltaic cell can be capable of being reversible pulled in or out of the telescoping article.

Implementations can provide one or more of the following advantages.

Without wishing to be bound by theory, it is believed that the devices allow safe transportation and storage of panels of photovoltaic cells. The tube or tubes can protect the panel or panels stored therein from any dust, water or dirt found in the fields or at a location of storage. Moreover, the panel or panels can be protected from mechanical damage. If the devices are incidentally dropped to the floor, the panel or panels of photovoltaic cells can be protected from breakage or mechanical damage when stored in the tube.

Without wishing to be bound by theory, it is believed that the devices allow easy transportation and handling of the panel or panels of photovoltaic cells in the fields. The panel(s) can be significantly reduced in size, when it/they are pulled into the tube or tubes. Moreover, by collapsing the telescoping tube, the length of the device can be significantly reduced. Thus, in the collapsed state, the storage of the device requires much smaller space and the handling of the device is much easier.

Other features and advantages of the invention will be apparent from the description, drawings, and claims.

### DESCRIPTION OF DRAWINGS

FIG. 1 is a perspective view of a device in an extended state where a panel is pulled out of the device.

FIG. 2 is a top view of a device in an extended state where a panel is pulled out of the device.

FIG. 3 is a perspective view of a device in a collapsed state.

FIG. 4 is a cross-sectional view of an embodiment of a photovoltaic cell.

Like reference symbols in the various drawings indicate like elements.

### DETAILED DESCRIPTION

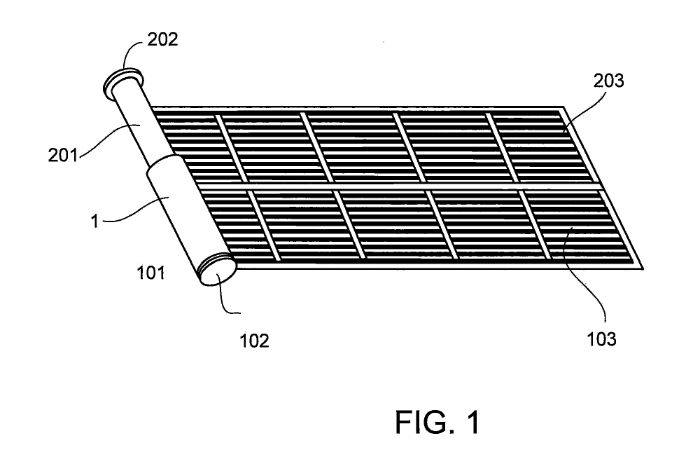

FIG. 1 shows a telescoping device 1 in an extended state. Telescoping device 1 has tubes 101 and 201, caps 102 and 202, panels 103 and 203 containing a plurality of photovoltaic cells, and openings 104, 105 and 204. Openings 104 and 105 are located at the longitudinal ends of tube 101. Opening 204 is located on the longitudinal end of tube 204. Caps 102 and 202 cover openings 104 and 204, respectively. One portion of tube 201 is inserted into tube 101 through opening 105. Each of tubes 101 and 201 has a slot (not shown in FIG. 1), through which panel 103 or 203 can be reversibly pulled in or out of tube 101 or 201.

Tubes 101 and 201 can include any material suitable to be formed as a tube. Tubes 101 and 201 can be flexible, semi-rigid, or rigid. In some implementations, tubes 101 and 201 can be formed of a non-transparent material, a semitransparent material or a transparent material. In some implementations, tubes 101 and 201 can include wood, plastic or metal. In general, the outer diameter of the second tube 201 is smaller than the inner diameter of the first tube 101, so that at least a portion of the second tube 201 can easily be moved within the first tube 101 when the second tube 201 is inserted in the first tube 101.

When telescoping device 1 is in an extended state, at least a portion of tube 201 is pulled out of tube 101. When telescoping device 1 is in a collapsed state, the entire tube 201 is inserted into tube 101.

Each Slot on tubes 101 and 201 can have any suitable dimension and size as long as panel 103 or 203 can be reversibly pulled in and out through the slot. In some implementations, each slot has about the same length and width as panel 103 or 203. Without wishing to be bound by theory, it is believed that if each slot has about the same length and width as panel 103 or 203, panel 103 or 203 can be pulled in and out of tube 101 or 201 through the slot without any gap between panel 103 or 203 and the slot, thereby preventing any dirt, dust or water from contaminating panel 103 or 203 inside a tube.

Caps 102 and 202 can be configured to cover openings 104 and 204, respectively. In general, caps 102 and 202 can be made of any suitable material. For example, caps 102 and 202 can be made of wood, plastic, or metal. In some implementations, caps 102 and 202 can be formed of a non-transparent material, a semitransparent material or a transparent material. In some implementations, caps 102 and 202 can be flexible, semi-rigid, or rigid.

Without wishing to be bound by theory, it is believed that when caps 102 and 202 respectively cover openings 104 and 204, dust, water or dirt can be efficiently prevented from entering device 1 and contaminating panels 103 and 203 therein. Further, it is believed that because panels 103 and 203 can be reversible pulled in and out of tubes 101 and 201, the effectiveness of the photovoltaic cells on panels 103 and 203 will not be diminished when device 1 is used in the field.

Turning to panels 103 and 203, at least a portion of the first panel 103 is configured to be reversibly pulled in or out of the first tube 101 through a first slot on tube 101, and at least a portion of a second panel 203 is configured to be reversibly pulled in or out of the second tube 201 through a second slot on tube 201. In some implementations, panel 103 or 203 can be entirely pulled in or out of tube 101 or 201 through the first or second slot.

Without wishing to be bound by theory, it is believed that an advantage of telescoping device 1 is that when panels 103 and 203 are pulled out of tubes 101 and 201, the photovoltaic cells on panels 103 and 203 can most efficiently make use of the light to generate electricity, and when panels 103 and 203 are pulled into tubes 101 and 201, they can be most efficiently and safely stored in tubes 101 and 201.

In general, panel 103 or 203 can be flexible or semi-rigid. For example, panel 103 or 203 can have a flexural modulus of less than about 5,000 megapascals (e.g., less than about 2,500 megaPascals, less than about 1,000 megapascals). In some embodiments, different regions of panel 103 or 203 can be flexible, semi-rigid, or inflexible (e.g., one or more regions flexible and one or more different regions semi-rigid, one or more regions flexible and one or more different regions inflexible). In some implementations, all regions of panel 103 or 203 are formed of flexible materials (e.g., a polymer). In some implementations, panel 103 or 203 can form a roll with a relatively small radius in tube 101 or 201. For example, panel 103 or 203 can form a roll having a radius of at least about 0.1 inches (e.g., at least about 0.25 inches, at least about 0.5 inches, at least about 1 inch, or at least about 2 inches) and/or at most about 5 inches (e.g., at most about 4 inches, at most about 2 inches, or at most 1 inches). In such implementations, panel 103 or 203 can be quickly unrolled to form a panel as it is being pulled out of tube 101 or 201. For example, panel 103 or 203 can be at least about 0.001 inches (e.g., at least about 0.01 inches, at least about 0.02 inches, or at least about 0.05 inches) thick and/or at most about 0.5 inches (e.g., at most about 0.1 inches, at most about 0.05 inches, or at most about 0.02) thick.

Panel 103 or 203 generally includes at least one (e.g., two, three, five, ten, 15, 20, 50, 100, or 500) photovoltaic cell. In some implementations, the photovoltaic cells can be disposed on one side of panel 103 or 203. In some implementations, the photovoltaic cells can be disposed on both sides of panel 103 or 203.

The photovoltaic cells suitable for use on panel 103 or 203 can be any photovoltaic cells, such as organic photovoltaic cells, dye sensitized photovoltaic cells, or hybrid photovoltaic cells. The photovoltaic cells can also be inorganic photovoltaic cells with an photoactive material formed of amorphous silicon, cadmium selenide, cadmium telluride, copper indium selenide, and copper indium gallium selenide. In some implementations, a hybrid photovoltaic cell can be integrated with one of the photoactive polymers described herein.

In some implementations, telescoping device 1 further includes first and second members (not shown in FIG. 1). The first member is attached to the first panel 103 and prevents the separation of the first panel 103 from device 1 when the first panel 103 is pulled out of the first tube 101 through the slot. The second member is attached to the second panel 203 and prevents the separation of the second panel 203 from device 1 when the second panel 203 is pulled out of the second tube 201 through the slot. As used herein if referring to a member, the member can be either first member or second member or both.

The member can be a mandrel concentrically disposed in the tube 101 or 201. Panel 103 or 203 can roll onto the mandrel when the panel 103 or 203 is pulled into device 1 through the slot. Without wishing to be bound by theory, it is believed that if the member is a mandrel upon which panel 103 or 203 can be rolled, panel 103 or 203 can most efficiently be stored in tube 101 or 201 when panel 103 or 203 is pulled into tube 101 or 201 through the slot.

The member can be formed of any material, as long as it can prevent the separation of the panel from the tube 101 or 201. In some implementations, the member can be formed of metal, plastic or wood.

In some implementations, the member is configured to have dimensions or shapes that make it impossible for the member to pass through the slot of tube 101 or 201 and be separated from device 1. In some implementations, the member is attached to the inner wall of tube 101 or 201. In some implementation, the member can have a retraction mechanism, which can be used to pull panel 103 or 203 into tube 101 or 201. In some implementations, the retraction mechanism can be spring loaded for automatic rewinding. In other implementations, the retraction mechanism can be designed for a manual rewinding. For example, the retraction mechanism can include a lever or knob extending thought cap 102 or 202 and being in operable connection with the member in tube 101 or 201. In this case, panel 103 or 203 can be manually wrapped around the member using the lever or knob.

Without wishing to be bound by theory, it is believed that when a member is attached to panel 103 or 203 and prevents the separation of panel 103 or 203 from device 1, panel 103 or 203 will not get lost in the field and can easily be pulled back into tube 101 or 201 without having to be manually inserted into the slot of the tube 101 or 201.

In some implementations, the first panel 101 can be attached to the second panel 201 when the first and second panels are pulled out of the first and the second slots. Any means suitable for attaching the panels 101 and 201 can be used, e.g., hooks made of metal or plastics. In such implementations, panels 101 and 201 form two sub-panels of the attached panel.

Without wishing to be bound by theory, it is believed that when the first panel 101 can be attached to the second panel 201 when the first and second panels are pulled out of the first and the second slots, device 1 has an improved overall mechanical stability. Moreover, an optimal energy transformation by the photovoltaic cells of the panels can be achieved by preventing any overlap of the first and the second panel.

In some implementations, telescoping device 1 can include more than two (e.g., any of three to ten) telescoping tubes, each of which contains a panel having one or more photovoltaic cells and a slot through which the panel can be reversibly pulled in or out of the tube. Without wishing to be bound by theory, it is believed that such a device 1 can store a large number of photovoltaic cells without significantly increasing the storage space.

In general, the more tubes are used in telescoping device 1, the smaller telescoping device 1 can be at a collapsed state relative to the length of the telescoping device 1 at an extended state. However, the more tubes are used in telescoping device 1, the more complicated is the manufacturing process as more tubes have to be inserted into each other and the strength of the telescoping device 1 may also decrease as the walls of the tubes may have to be made thinner. From a practical standpoint, device 1 with two to ten tubes is optimal. However, higher numbers of further tubes can also be used in telescoping device 1. In general, a device 1 including a first tube and (n-1) further tubes has a first length at a collapsed state and a second length at an extended state and the second length can be at most n-times as large as the first length of the device 1. In some implementations, n can be any integer ranging from two to ten.

In general, telescoping device 1 and its components can have any suitable dimensions. For example, the ratio between the outer diameter and the length of tube 101 can be any ratio suitable to store a panel having photovoltaic cells. For practical reasons, a ratio of from about 1:2 to about 1:4 can be used. In some implementations, tube 101 can have an outer diameter of about 2.75 inches and a length of about 8.38 inches.

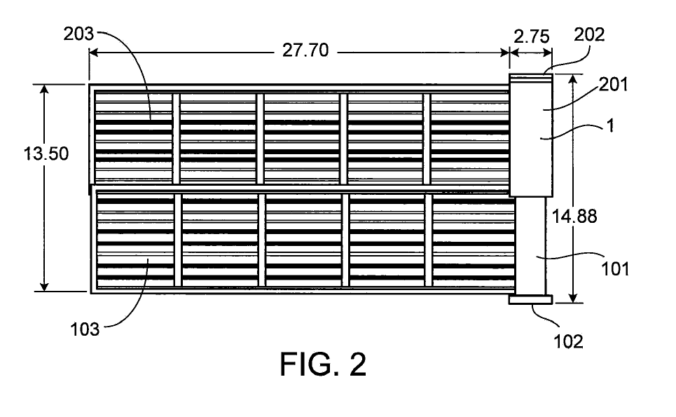

FIG. 2 shows a telescoping device 1 having an exemplary dimension. As shown in FIG. 2, telescoping device 1 has a total length of 14.88 inches in an extended state, tube 101 has an outer diameter of 2.75 inches, and panels 103 and 203 both have a length of 27.70 inches. The total width of panels 103 and 203 is 13.50 inches, which is slightly smaller than the length of telescoping device 1 in the extended state.

In general, the dimensions mentioned above can vary as desired. For example, the total length of telescoping device 1 in an extended state can be at least about 5 inches (e.g., at least about 10 inches, at least about 30 inches, or at least about 50 inches) or at most about 100 inches (e.g., at most about 70 inches, at most about 40 inches, or at most about 20 inches). As another example, tube 101 can have an outer diameter at least about 1 inch (e.g., at least about 2 inches, at least about 3 inches, at least about 5 inches) or at most about 10 inches (e.g., at most about 7 inches, at most about 4 inches, or at most about 2 inches). As another example, panel 103 or 203 can have a length of at least about 10 inches (e.g., at least about 30 inches, at least about 50 inches, or at least about 70 inches) or at most about 100 inches (e.g., at most about 80 inches, at most about 60 inches, or at most about 40 inches). As still another example, the total width of panels 103 and 203 can be at least about 0.1 inches (e.g., at least about 0.2 inches, at least about 0.5 inches, or at least about 1 inch) or at most about 5 inches (e.g., at most about 4 inches, at most about 2 inches, or at most about 1 inch) smaller than the length of telescoping device 1 in the extended state.

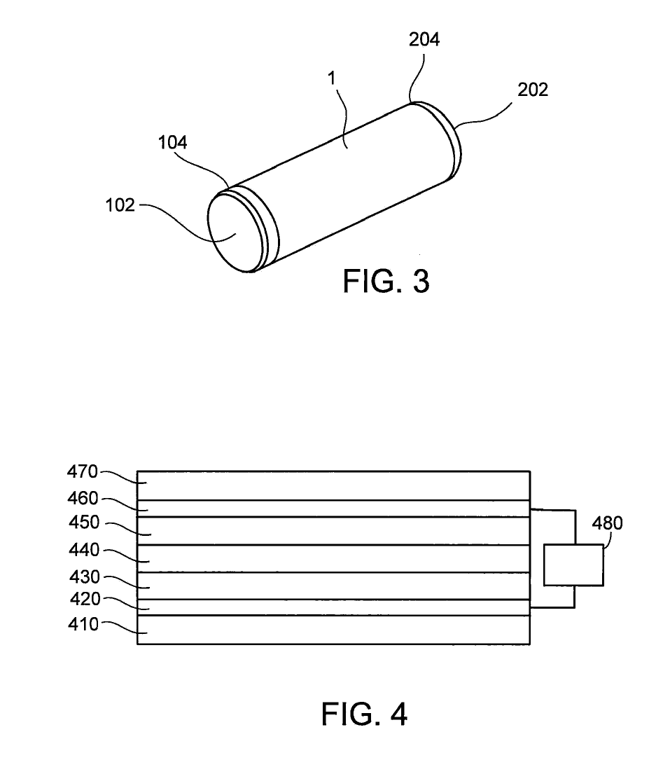

FIG. 3 shows a telescoping device 1 with the telescoping tubes in a collapsed state. In telescoping device 1, caps 102 and 202 cover the openings 104 and 204, respectively. To form a collapsed state, each of panels 103 and 203 can be first pulled into tubes 101 and 201 (e.g., rolled on mandrels in tubes 101 and 201) and tube 201 can then be collapsed into tube 101. Telescoping device 1 can have a significantly reduced size in a collapsed state and can be easily transported or stored.

FIG. 4 shows a photovoltaic cell that can be used in the telescoping devices shown in FIGS. 1-3. The photovoltaic cell has a substrate 410, an electrode 420, an optional hole blocking layer 430, a photoactive layer 440, a hole carrier layer 450, an electrode 460, and a substrate 470. The photovoltaic cell is electrically connected to an external load 480.

Substrate 410 is generally formed of a transparent material. As referred to herein, a transparent material is a material which, at the thickness used in a photovoltaic cell, transmits at least about 60% (e.g., at least about 70%, at least about 75%, at least about 80%, at least about 85%) of incident light at a wavelength or a range of wavelengths used during operation of the photovoltaic cell. Exemplary materials from which substrate 410 can be formed include polyethylene terephthalates, polyimides, polyethylene naphthalates, polymeric hydrocarbons, cellulosic polymers, polycarbonates, polyamides, polyethers, and polyether ketones. In certain implementations, the polymer can be a fluorinated polymer. In some implementations, combinations of polymeric materials are used. In certain implementations, different regions of substrate 410 can be formed of different materials.

In general, substrate 410 can be flexible, semi-rigid or rigid (e.g., glass). In some implementations, substrate 410 has a flexural modulus of less than about 5,000 megaPascals (e.g., less than about 1,000 megaPascals or less than about 5,00 megapascals). In certain implementations, different regions of substrate 410 can be flexible, semi-rigid, or inflexible (e.g., one or more regions flexible and one or more different regions semi-rigid, one or more regions flexible and one or more different regions inflexible).

Typically, substrate 410 is at least about one micron (e.g., at least about five microns, at least about 10 microns) thick and/or at most about 1,000 microns (e.g., at most about 500 microns thick, at most about 300 microns thick, at most about 200 microns thick, at most about 100 microns, at most about 50 microns) thick.

Generally, substrate 410 can be colored or non-colored. In some implementations, one or more portions of substrate 410 is/are colored while one or more different portions of substrate 410 is/are non-colored. Substrate 410 can have one planar surface (e.g., the surface on which light impinges), two planar surfaces (e.g., the surface on which light impinges and the opposite surface), or no planar surfaces. A non-planar surface of substrate 410 can, for example, be curved or stepped. In some implementations, a non-planar surface of substrate 410 is patterned (e.g., having patterned steps to form a Fresnel lens, a lenticular lens or a lenticular prism).

Electrode 420 is generally formed of an electrically conductive material. Exemplary electrically conductive materials include electrically conductive metals, electrically conductive alloys, electrically conductive polymers, and electrically conductive metal oxides. Exemplary electrically conductive metals include gold, silver, copper, aluminum, nickel, palladium, platinum, and titanium. Exemplary electrically conductive alloys include stainless steel (e.g., 332 stainless steel, 316 stainless steel), alloys of gold, alloys of silver, alloys of copper, alloys of aluminum, alloys of nickel, alloys of palladium, alloys of platinum and alloys of titanium. Exemplary electrically conducting polymers include polythiophenes (e.g., doped poly(3,4-ethylenedioxythiophene) (doped PEDOT)), polyanilines (e.g., doped polyanilines), polypyrroles (e.g., doped polypyrroles). Exemplary electrically conducting metal oxides include indium tin oxide, fluorinated tin oxide, tin oxide and zinc oxide. In some implementations, combinations of electrically conductive materials are used.

In some implementations, electrode 420 can include a mesh electrode. Examples of mesh electrodes are described in co-pending U.S. Patent Application Publication Nos. 20040187911 and 20060090791, the entire contents of which are hereby incorporated by reference. In some implementations, a combination of the materials described above can be used to in electrode 420.

Hole blocking layer 430 is generally formed of a material that, at the thickness used in photovoltaic cell, transports electrons to electrode 420 and substantially blocks the transport of holes to electrode 420. Examples of materials from which the hole blocking layer 430 can be formed include LiF, metal oxides (e.g., zinc oxide, titanium oxide), and amines (e.g., primary, secondary, or tertiary amines). Examples of amines suitable for use in a hole blocking layer 430 have been described, for example, in co-pending U.S. Utility application Ser. No. 12/109,828, the entire contents of which are hereby incorporated by reference.

Without wishing to be bound by theory, it is believed that when photovoltaic cell includes a hole blocking layer 430 made of amines, the hole blocking layer can facilitate the formation of ohmic contact between photoactive layer 440 and electrode 420 without being exposed to UV light, thereby reducing damage to photovoltaic cell resulted from UV exposure.

Typically, hole blocking layer 430 is at least 0.02 micron (e.g., at least about 0.03 micron, at least about 0.04 micron, at least about 0.05 micron) thick and/or at most about 0.5 micron (e.g., at most about 0.4 micron, at most about 0.3 micron, at most about 0.2 micron, at most about 0.1 micron) thick.

Photoactive layer 440 contains in general an electron acceptor material (e.g., an organic electron acceptor material) and an electron donor material (e.g., an organic electron donor material).

Electron donor materials can include conducting polymers (e.g., a conjugated organic polymer), which generally have a conjugated portion. Conjugated polymers are characterized in that they have overlapping π orbitals, which contribute to the conductive properties. Conjugated polymers may also be characterized in that they can assume two or more resonance structures. The conjugated organic polymer may be linear or branched, so long as the polymer retains its conjugated nature.

Examples of suitable electron donor materials include one or more of polyacetylene, polyaniline, polyphenylene, poly(p-phenylene vinylene), polythienylvinylene, polythiophene, polyporphyrins, porphyrinic macrocycles, polymetallocenes, polyisothianaphthalene, polyphthalocyanine, a discotic liquid crystal polymer, and a derivative or a combination thereof. Exemplary derivatives of the electron donor materials include derivatives having pendant groups, e.g., a cyclic ether, such as epoxy, oxetane, furan, or cyclohexene oxide. Derivatives of these materials may alternatively or additionally include other substituents. For example, thiophene components of electron donor may include a phenyl group, such as at the 3 position of each thiophene moiety. As another example, alkyl, alkoxy, cyano, amino, and/or hydroxy substituent groups may be present in any of the polyphenylacetylene, polydiphenylacetylene, polythiophene, and poly(p-phenylene vinylene) conjugated polymers. In some implementations, the electron donor material is poly(3-hexylthiophene) (P3HT). In certain implementations, photoactive layer 440 can include a combination of electron donor materials.

Electron acceptor materials can include a material selected from the group consisting of fullerenes, inorganic nanoparticles, oxadiazoles, discotic liquid crystals, carbon nanorods, inorganic nanorods, polymers containing CN groups, polymers containing CF3 groups, and combinations thereof.

As used herein, the term “fullerene” means a compound, e.g., a molecule, including a three-dimensional carbon skeleton having a plurality of carbon atoms. The carbon skeleton of such fullerenes generally forms a closed shell, which may be, e.g., spherical or semi-spherical in shape. Alternatively, the carbon skeleton may form an incompletely closed shell, such as, e.g., a tubular shape. Carbon atoms of fullerenes are generally linked to three nearest neighbors in a tetrahedral network. In some implementations, photoactive layer 440 can include one or more unsubstituted fullerenes and/or one or more substituted fullerenes.

Unsubstituted fullerenes may be designated as Cj, where j is an integer related to the number of carbon atoms of the carbon skeleton. For example, C60 defines a truncated icosahedron including 32 faces, of which 12 are pentagonal and 20 are hexagonal. Other suitable fullerenes include, e.g., Cj where j may be at least 50 and may be less than about 450. Unsubstituted fullerenes can generally be produced by the high temperature reaction of a carbon source, such as elemental carbon or carbon containing species. For example, sufficiently high temperatures may be created using laser vaporization, an electric arc, or a flame. Subjecting a carbon source to high temperatures forms a carbonaceous deposit from which various unsubstituted fullerenes are obtained. Unsubstituted fullerenes can include C₆₀, C₇₀, C₇₆, C₇₈, C₈₂, C₈₄, and C₉₂.

Typically, the unsubstituted fullerenes can be purified using a combination of solvent extraction and chromatography.

Substituted fullerene include fullerenes containing one or more substituents. Substituents can include alkyl, alkenyl, alkynyl, cycloalkyl, cycloalkenyl, alkoxy, aryl, aryloxy, heteroaryl, heteroaryloxy, amino, alkylamino, dialkylamino, arylamino, diarylamino, hydroxyl, halogen, thio, alkylthio, arylthio, alkylsulfonyl, arylsulfonyl, cyano, nitro, acyl, acyloxy, carboxyl, and carboxylic ester. These substituents can be further substituted by one or more suitable substituents. Substituted fullerenes can be C61-phenyl-butyric acid glycidol ester (PCBG), fullerenes substituted with C1-C20 alkoxy optionally further substituted with C1-C20 alkoxy and/or halo (e.g., (OCH₂CH₂)₂OCH₃ or OCH₂CF₂OCF₂CF₂OCF₃), [6,6]-phenyl C61-butyric acid methyl ester (C61 -PCBM) or [6,6]-phenyl C71 -butyric acid methyl ester (C71-PCBM).

Without wishing to be bound by theory, it is believed that fullerenes substituted with long-chain alkoxy groups (e.g., oligomeric ethylene oxides) or fluorinated alkoxy groups have improved solubility in organic solvents and can form a photoactive layer 440 with improved morphology. In some implementations, the electron acceptor material can include one or more of the polymers described above. In certain implementations, a combination of electron acceptor materials can be used in photoactive layer 440.

Substituted fullerenes can be prepared by any suitable methods. For example, alkylfullerene derivatives can be prepared by reacting fullerenes with organic alkyl lithium or alkyl Grignard reagents and then with alkyl halides. As another example, PCBM can be prepared by reacting C60 with methyl 4-benzoylbutyrate p-tosylhydrazone in the presence of a base. PCBM can be further modified to obtain other substituted fullerenes (e.g., PCBG).

Without wishing to be bound by any theory, it is believed that a photovoltaic cell containing a mixture of one or more unsubstituted fullerenes and one or more substituted fullerenes in photoactive layer 440 can exhibit enhanced thermal stability. For example, after being heated at an elevated temperature for a period of time, a photovoltaic cell containing a mixture of one or more unsubstituted fullerenes and one or more substituted fullerenes can undergo a relatively small change in efficiency.

In general, the weight ratio of the unsubstituted fullerene to the substituted fullerene can be varied as desired. The weight ratio of the unsubstituted fullerene to the substituted fullerene can be at least about 1:20 (e.g., at least about 1:10, at least about 1:5, at least about 1:3, or at least about 1:1) and/or at most about 10:1 (e.g., at most about 5:1 or at most about 3:1).

In some implementations, photoactive layer 440 can include one or more non-fullerene electron acceptor materials. Examples of suitable non-fullerene electron acceptor materials include oxadiazoles, carbon nanorods, discotic liquid crystals, inorganic nanoparticles (e.g., nanoparticles formed of zinc oxide, tungsten oxide, indium phosphide, cadmium selenide and/or lead sulphide), inorganic nanorods (e.g., nanorods formed of zinc oxide, tungsten oxide, indium phosphide, cadmium selenide and/or lead sulphide), or polymers containing moieties capable of accepting electrons or forming stable anions (e.g., polymers containing CN groups, polymers containing CF₃ groups).

In some implementations, photoactive layer 440 includes an oriented electron donor material (e.g., a liquid crystal (LC) material), an electroactive polymeric binder carrier (e.g., P3HT), and a plurality of nanocrystals (e.g., oriented nanorods including at least one of ZnO, WO₃, or TiO₂). The liquid crystal material can be, for example, a discotic nematic LC material, including a plurality of discotic mesogen units. Each unit can include a central group and a plurality of electroactive arms. The central group can include at least one aromatic ring (e.g., an anthracene group). Each electroactive arm can include a plurality of thiophene moieties and a plurality of alkyl moieties. Within the photoactive layer 440, the units can align in layers and columns. Electroactive arms of units in adjacent columns can interdigitate with one another facilitating electron transfer between units. Also, the electroactive polymeric carrier can be distributed amongst the LC material to further facilitate electron transfer. The surface of each nanocrystal can include a plurality of electroactive surfactant groups to facilitate electron transfer from the LC material and polymeric carrier to the nanocrystals. Each surfactant group can include a plurality of thiophene groups. Each surfactant can be bound to the nanocrystal via, for example, a phosphonic end-group. Each surfactant group also can include a plurality of alkyl moieties to enhance solubility of the nanocrystals in the photoactive layer 440.

Other electron donor materials and electron acceptor materials are disclosed in commonly owned co-pending application U.S. patent application Ser. No. 11/486,536, filed Jul. 14, 2006, the contents of which are hereby incorporated by reference.

Photoactive layer 440 can also include other photovoltaic materials. Other photovoltaic materials include, for example, the materials described in commonly owned co-pending U.S. Patent Application Publication No. 2005-0263179, U.S. Patent Application Publication No. 2007-0020526, U.S. Patent Application Publication No. 2007-0181179, U.S. patent application Ser. No. 11/734,118, U.S. patent application Ser. No. 11/851,559, and U.S. patent application Ser. No. 11/851,591. The entire contents of the just-mentioned patent applications are hereby incorporated by reference.

Generally, photoactive layer 440 is sufficiently thick to be relatively efficient at absorbing photons impinging thereon to form corresponding electrons and holes, and sufficiently thin to be relatively efficient at transporting the holes and electrons to electrodes of the device 1. In certain implementations, photoactive layer 440 is at least 0.05 micron (e.g., at least about 0.1 micron, at least about 0.2 micron, or at least about 0.3 micron) thick and/or at most about 1 micron (e.g., at most about 0.5 micron or at most about 0.4 micron) thick. In some implementations, photoactive layer 440 is from about 0.1 micron to about 0.2 micron thick.

Hole carrier layer 450 is generally formed of a material that, at the thickness used in photovoltaic cell, transports holes to electrode 460 and substantially blocks the transport of electrons to electrode 460. Examples of materials from which layer 450 can be formed include polythiophenes (e.g., PEDOT), polyanilines, polycarbazoles, polyvinylcarbazoles, polyphenylenes, polyphenylvinylenes, polysilanes, polythienylenevinylenes, polyisothianaphthanenes, and copolymers thereof. In some implementations, hole carrier layer 450 can include a dopant used in combination with a semiconductive polymer. Examples of dopants include poly(styrene-sulfonate)s, polymeric sulfonic acids, or fluorinated polymers (e.g., fluorinated ion exchange polymers).

In some implementations, the materials that can be used to form hole carrier layer 450 include metal oxides, such as titanium oxides, zinc oxides, tungsten oxides, molybdenum oxides, copper oxides, strontium copper oxides, or strontium titanium oxides. The metal oxides can be either undoped or doped with a dopant. Examples of dopants for metal oxides includes salts or acids of fluoride, chloride, bromide, and iodide.

In some implementations, the materials that can be used to form hole carrier layer 450 include carbon allotropes (e.g., carbon nanotubes). The carbon allotropes can be embedded in a polymer binder.

In some implementations, the hole carrier materials can be in the form of nanoparticles. The nanoparticles can have any suitable shape, such as a spherical, cylindrical, or rod-like shape.

In some implementations, hole carrier layer 450 can include combinations of hole carrier materials described above.

In general, the thickness of hole carrier layer 450 (i.e., the distance between the surface of hole carrier layer 450 in contact with photoactive layer 440 and the surface of electrode 460 in contact with hole carrier layer 450) can be varied as desired. Typically, the thickness of hole carrier layer 450 is at least 0.01 micron (e.g., at least about 0.05 micron, at least about 0.1 micron, at least about 0.2 micron, at least about 0.3 micron, or at least about 0.5 micron) and/or at most about five microns (e.g., at most about three microns, at most about two microns, or at most about one micron). In some implementations, the thickness of hole carrier layer 450 is from about 0.01 micron to about 0.5 micron.

Electrode 460 is generally formed of an electrically conductive material, such as one or more of the electrically conductive materials described above. In some implementations, electrode 460 is formed of a combination of electrically conductive materials. In certain implementations, electrode 460 can be formed of a mesh electrode.

Substrate 470 can be identical to or different from substrate 410. In some implementations, substrate 470 can be formed of one or more suitable polymers, such as the polymers used in substrate 410 described above.

External load 480 can be any load suitable for being used as external load. Examples of suitable external load include portable electronic devices (e.g., mobile phones, laptops, flash lights, portable lamps, radios, or GPS systems) and rechargeable batteries.

In general, the methods of preparing each layer in photovoltaic cells described in FIG. 4 can vary as desired. In some implementations, a layer can be prepared by a liquid-based coating process. In certain implementations, a layer can be prepared via a gas phase-based coating process, such as chemical or physical vapor deposition processes.

The term “liquid-based coating process” mentioned herein refers to a process that uses a liquid-based coating composition. Examples of the liquid-based coating composition include solutions, dispersions, or suspensions. The liquid-based coating process can be carried out by using at least one of the following processes: solution coating, ink jet printing, spin coating, dip coating, knife coating, bar coating, spray coating, roller coating, slot coating, gravure coating, flexographic printing, or screen printing. Examples of liquid-based coating processes have been described in, for example, commonly-owned co-pending U.S. Application Publication No. 2008-0006324, the entire contents of which are hereby incorporated by reference.

In some implementations, when a layer includes inorganic semiconductor nanoparticles, the liquid-based coating process can be carried out by (1) mixing the nanoparticles with a solvent (e.g., an aqueous solvent or an anhydrous alcohol) to form a dispersion, (2) coating the dispersion onto a substrate, and (3) drying the coated dispersion. In certain implementations, a liquid-based coating process for preparing a layer containing inorganic metal oxide nanoparticles can be carried out by (1) dispersing a precursor (e.g., a titanium salt) in a suitable solvent (e.g., an anhydrous alcohol) to form a dispersion, (2) coating the dispersion on a substrate, (3) hydrolyzing the dispersion to form an inorganic semiconductor nanoparticles layer (e.g., a titanium oxide nanoparticles layer), and (4) drying the inorganic semiconductor material layer. In certain implementations, the liquid-based coating process can be carried out by a sol-gel process (e g., by forming metal oxide nanoparticles as a sol-gel in a dispersion before coating the dispersion on a substrate).

In general, the liquid-based coating process used to prepare a layer containing an organic semiconductor material can be the same as or different from that used to prepare a layer containing an inorganic semiconductor material. In some implementations, when a layer includes an organic semiconductor material, the liquid-based coating process can be carried out by mixing the organic semiconductor material with a solvent (e.g., an organic solvent) to form a solution or a dispersion, coating the solution or dispersion on a substrate, and drying the coated solution or dispersion.

In some implementations, the photovoltaic cells described in FIG. 4 can be prepared in a continuous manufacturing process, such as a roll-to-roll process, thereby significantly reducing the manufacturing cost. Examples of roll-to-roll processes have been described in, for example, commonly-owned co-pending U.S. Application Publication No. 2005-0263179, the entire contents of which are hereby incorporated by reference.

In general, during use, light impinges on the surface of substrate 410, and passes through substrate 410, electrode 420, and optional hole blocking layer 430. The light then interacts with photoactive layer 440, causing electrons to be transferred from the electron donor material (e.g., a polymer described above) to the electron acceptor material (e.g., C61-PCBM). The electron acceptor material then transmits the electrons through hole blocking layer 430 to electrode 420, and the electron donor material transfers holes through hole carrier layer 450 to electrode 460. Electrodes 420 and 460 are in electrical connection via an external load 480 so that electrons pass from electrode 420, through the load, and to electrode 460.

In some implementations, the efficiency of photovoltaic cell after being heated at a temperature of at least about 50° C. (e.g., at least about 100° C., at least about 150° C., at least about 170° C., at least about 200° C., at least about 225° C.) for at least about 5 minutes (e.g., at least about 10 minutes, at least about 15 minutes, at least about 20 minutes, at least about 30 minutes, at least about 60 minutes, at least about 120 minutes) is at least about 50% (e.g., at least about 60%, at least about 70%, at least about 80%, at least about 90%, at least about 95%, at least about 98%) of the efficiency before being heated.

Photovoltaic cell can have an efficiency of at least about 0.5% (e.g., at least about 1%, at least about 2%, at least about 3%, or at least about 4%). The efficiency of a photovoltaic cell refers to the ratio of the solar energy that reaches the cell to the electrical energy that is produced by the cell. Efficiency of a photovoltaic cell can be obtained by methods known in the art. For example, it can be determined from a current-voltage curve derived based on a photovoltaic cell. In some implementations, the unsubstituted fullerene and the substituted fullerene in photoactive layer 440 can be substantially non-phase separated.

Without wishing to be bound by theory, it is believed that if the photovoltaic cells on panel 103 or 203 have the characteristics described herein (e.g., high efficiency and high flexibility), telescoping device 1 can provide for more efficient transformation of light energy to electrical energy and is further reduced in size and weight, which allows telescoping device 1 to be easily transported or stored. Without wishing to be bound by theory, it is believed that telescoping device 1 as described herein is reduced in size compared to the devices of the prior art.

Telescoping device 1 can be produced by methods similar to those used to producing telescopes, which are known in the art, except that it includes solar panels and slots through which the solar panels can be pulled in or out of telescoping device 1. For example, telescoping device 1 can be prepared by the following method: A flexible solar panel is prepared by attaching a plurality of pre-formed photovoltaic cells to a flexible substrate using an adhesive or by producing a plurality of photovoltaic cells (e.g., organic photovoltaic cells) on a flexible substrate in situ. After one end of the flexible solar panel is attached to a mandrel, the solar panel can be rolled up onto the mandrel. The article thus formed can subsequently be placed into a tube that includes a slot having the same or slight larger length so that the solar panel can be reversibly pulled in or out of the slot. One or more of such tubes having different dimensions (e.g., outer and/or inner diameters) can be inserted into each other to form a telescoping device 1. Finally, caps can be attached to each of the two openings of telescoping device 1 in order to close the telescoping device 1.

During use of telescoping device 1, panel 103 or 203 can be pulled out of the telescoping tube 102 or 201 through a slot so that the photovoltaic cells in telescoping device 1 can be exposed to light and thereby convert light energy into electricity energy. The first or second member described above can prevent the separation of the panel 103 or 203 from tube 101 or 201 when they are pulled out through the slots. When panel 103 or 203 is pulled out of tube 101 or 201, panel 103 or 203 can be split into at least two sub-panels by expanding the telescoping tube into an extended state. The sub-panels can be attached to each other in order to further stabilize the device 1 in the extended state. In order to fold the device 1, panel 103 or 203 can be detached from each other and then pulled into tube 101 or 201. Tube 201 can then be inserted into tube 101 to form telescoping device 1 in a collapsed state. Telescoping device 1 is then ready for transportation or storage.

While certain implementations have been disclosed, other implementations are also possible.

In some implementations, the electron donor or acceptor materials can include one or more polymers (e.g., homopolymers or copolymers). A polymer mentioned herein includes at least two identical or different monomer repeat units (e.g., at least 5 monomer repeat units, at least 10 monomer repeat units, at least 50 monomer repeat units, at least 100 monomer repeat units, or at least 500 monomer repeat units). A homopolymer mentioned herein refers to a polymer that includes only one type of monomer repeat units. A copolymer mentioned herein refers to a polymer that includes at least two co-monomer repeat units with different chemical structures.

In some implementations, electron donor or acceptor materials can include one or more of the following comonomer repeat units: a silacyclopentadithiophene moiety of formula (1), a cyclopentadithiophene moiety of formula (2), a benzothiadiazole moiety of formula (3), a thiadiazoloquinoxaline moiety of formula (4), a cyclopentadithiophene dioxide moiety of formula (5), a cyclopentadithiophene monoxide moiety of formula (6), a benzoisothiazole moiety of formula (7), a benzothiazole moiety of formula (8), a thiophene dioxide moiety of formula (9), a cyclopentadithiophene dioxide moiety of formula (10), a cyclopentadithiophene tetraoxide moiety of formula (11), a thienothiophene moiety of formula (12), a thienothiophene tetraoxide moiety of formula (13), a dithienothiophene moiety of formula (14), a dithienothiophene dioxide moiety of formula (15), a dithienothiophene tetraoxide moiety of formula (16), a tetrahydroisoindole moiety of formula (17), a thienothiophene dioxide moiety of formula (18), a dithienothiophene dioxide moiety of formula (19), a fluorene moiety of formula (20), a silole moiety of formula (21), a fluorenone moiety of formula (22), a thiazole moiety of formula (23), a selenophene moiety of formula (24), a thiazolothiazole moiety of formula (25), a cyclopentadithiazole moiety of formula (26), a naphthothiadiazole moiety of formula (27), a thienopyrazine moiety of formula (28), an oxazole moiety of formula (29), an imidazole moiety of formula (30), a pyrimidine moiety of formula (31), a benzoxazole moiety of formula (32), or a benzimidazole moiety of formula (33):

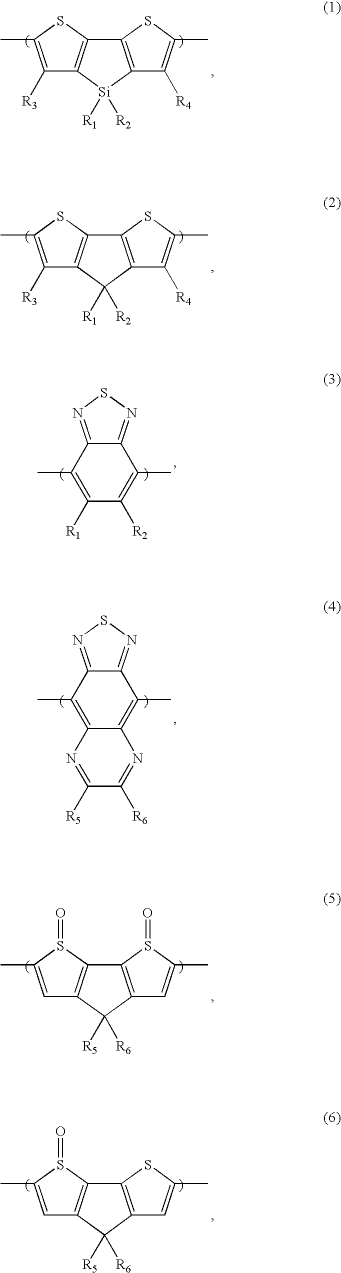

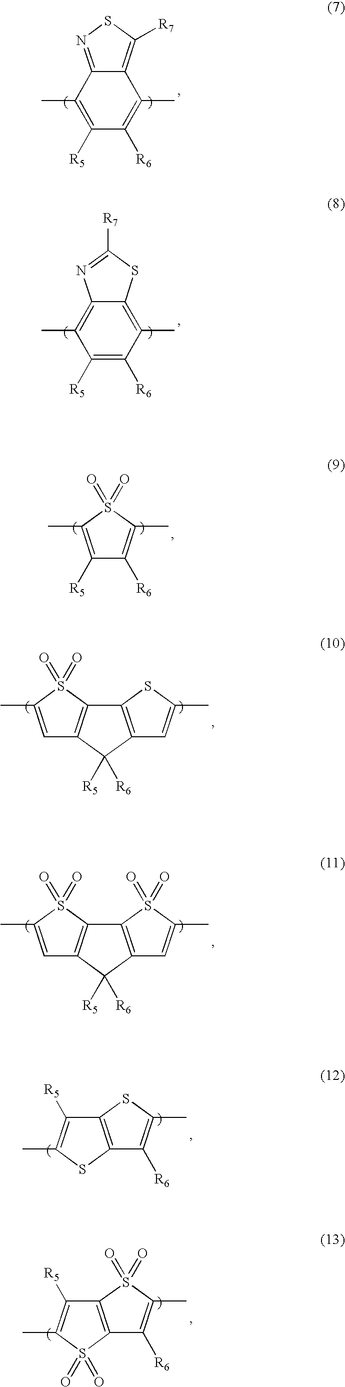

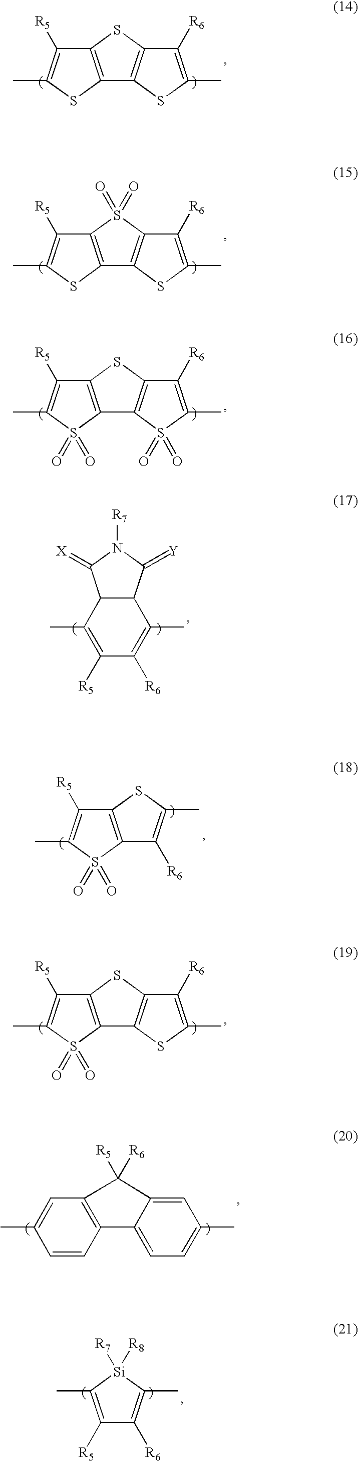

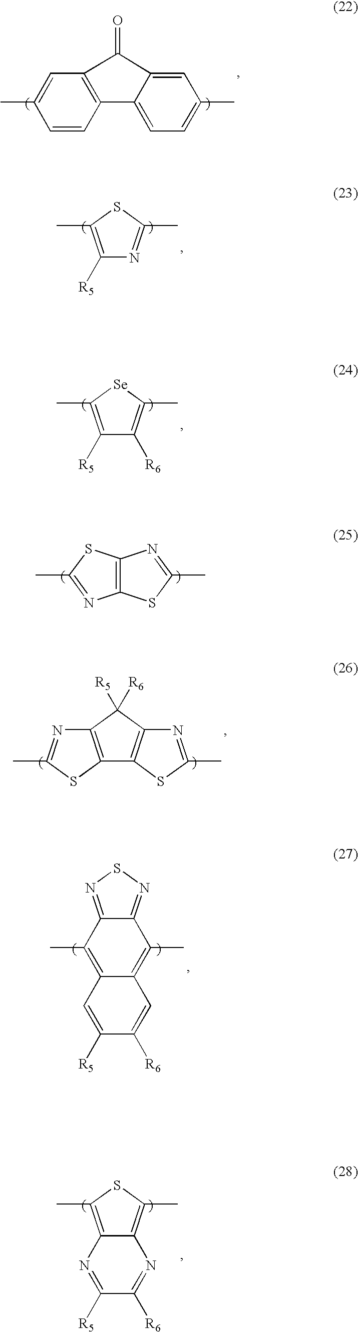

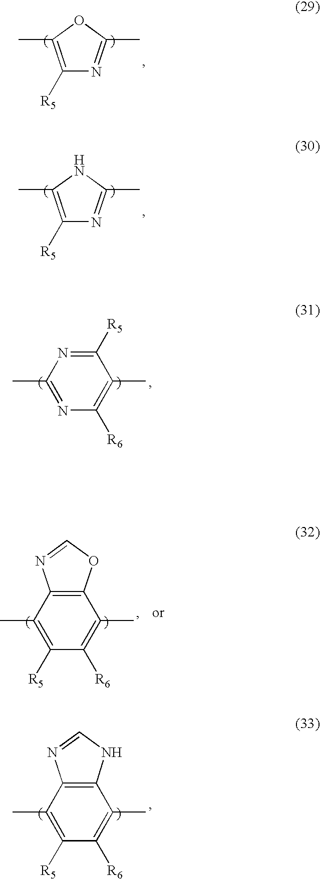

In the above formulas, each of X and Y, independently, is CH₂, O, or S; each of R₁, R₂, R₃, R₄, R₅, and R₆, independently, is H, C₁-C₂₀ alkyl, C₁-C₂₀ alkoxy, C₃-C₂₀ cycloalkyl, C₁-C₂₀ heterocycloalkyl, aryl, heteroaryl, halo, CN, OR, C(O)R, C(O)OR, or SO₂R, in which R is H, C₁-C₂₀ alkyl, C₁-C₂₀ alkoxy, aryl, heteroaryl, C₃-C₂₀ cycloalkyl, or C₁-C₂₀ heterocycloalkyl; and each of R₇ and R₈, independently, is H, C₁-C₂₀ alkyl, C₁-C₂₀ alkoxy, aryl, heteroaryl, C₃-C₂₀ cycloalkyl, or C₁-C₂₀ heterocycloalkyl.

An alkyl can be saturated or unsaturated and branch or straight chained. A C₁-C₂₀ alkyl contains 1 to 20 carbon atoms (e.g., one, two, three, four, five, six, seven, eight, nine, 10, 11, 12, 13, 14, 15, 16, 17, 18, 19, and 20 carbon atoms). Examples of alkyl moieties include —CH₃, —CH₂—, —CH₂═CH₂—, —CH₂—CH═CH₂, and branched —C₃H₇. An alkoxy can be branch or straight chained and saturated or unsaturated. An C₁-C₂₀ alkoxy contains an oxygen radical and 1 to 20 carbon atoms (e.g., one, two, three, four, five, six, seven, eight, nine, 10, 11, 12, 13, 14, 15, 16, 17, 18, 19, and 20 carbon atoms). Examples of alkoxy moieties include —OCH₃ and —OCH═CH—CH₃. A cycloalkyl can be either saturated or unsaturated. A C₃-C₂₀ cycloalkyl contains 3 to 20 carbon atoms (e.g., three, four, five, six, seven, eight, nine, 10, 11, 12, 13, 14, 15, 16, 17, 18, 19, and 20 carbon atoms). Examples of cycloalkyl moieties include cyclohexyl and cyclohexen-3-yl. A heterocycloalkyl can also be either saturated or unsaturated. A C₁-C₂₀ heterocycloalkyl contains at least one ring heteroatom (e.g., O, N, and S) and 1 to 20 carbon atoms (e.g., one, two, three, four, five, six, seven, eight, nine, 10, 11, 12, 13, 14, 15, 16, 17, 18, 19, and 20 carbon atoms). Examples of heterocycloalkyl moieties include 4-tetrahydropyranyl and 4-pyranyl. An aryl can contain one or more aromatic rings. Examples of aryl moieties include phenyl, phenylene, naphthyl, naphthylene, pyrenyl, anthryl, and phenanthryl. A heteroaryl can contain one or more aromatic rings, at least one of which contains at least one ring heteroatom (e.g., O, N, and S). Examples of heteroaryl moieties include furyl, furylene, fluorenyl, pyrrolyl, thienyl, oxazolyl, imidazolyl, thiazolyl, pyridyl, pyrmidinyl, quinazolinyl, quinolyl, isoquinolyl, and indolyl.

Alkyl, alkoxy, cycloalkyl, heterocycloalkyl, aryl, and heteroaryl mentioned herein include both substituted and unsubstituted moieties, unless specified otherwise. Examples of substituents on cycloalkyl, heterocycloalkyl, aryl, and heteroaryl include C₁-C₂₀ alkyl, C₃-C₂₀ cycloalkyl, C₁-C₂₀ alkoxy, aryl, aryloxy, heteroaryl, heteroaryloxy, amino, C₁-C₁₀ alkylamino, C₁-C₂₀ dialkylamino, arylamino, diarylamino, hydroxyl, halogen, thio, C₁-C₁₀ alkylthio, arylthio, C₁-C₁₀ alkylsulfonyl, arylsulfonyl, cyano, nitro, acyl, acyloxy, carboxyl, and carboxylic ester. Examples of substituents on alkyl include all of the above-recited substituents except C₁-C₂₀ alkyl. Cycloalkyl, heterocycloalkyl, aryl, and heteroaryl also include fused groups.

In some implementations, the electron donor or acceptor material can be a copolymer that includes first, second, and third comonomer repeat units, in which the first comonomer repeat unit includes a silacyclopentadithiophene moiety, the second comonomer repeat unit includes a cyclopentadithiazole moiety, and the third comonomer repeat unit includes a benzothiadiazole moiety.

In some implementations, the first comonomer repeat unit includes a silacyclopentadithiophene moiety of formula (1):

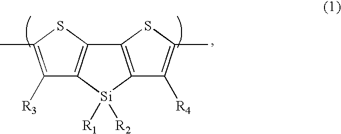

in which each of R₁, R₂, R₃, and R₄, independently, is H, C₁-C₂₀ alkyl, C₁-C₂₀ alkoxy, C₃-C₂₀ cycloalkyl, C₁-C₂₀ heterocycloalkyl, aryl, heteroaryl, halo, CN, OR, C(O)R, C(O)OR, or SO₂R; R being H, C₁-C₂₀ alkyl, C₁-C₂₀ alkoxy, aryl, heteroaryl, C₃-C₂₀ cycloalkyl, or C₁-C₂₀ heterocycloalkyl. In certain implementations, each of R₁ and R₂, independently, is C₁-C₂₀ alkyl (e.g., 2-ethylhexyl).

In some implementations, the second comonomer repeat unit includes a cyclopentadithiophene moiety of formula (2):

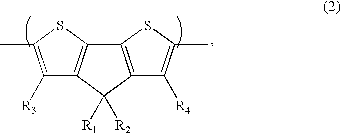

in which each of R₁, R₂, R₃, and R₄, independently, is H, C₁-C₂₀ alkyl, C₁-C₂₀ alkoxy, C₃-C₂₀ cycloalkyl, C₁-C₂₀ heterocycloalkyl, aryl, heteroaryl, halo, CN, OR, C(O)R, C(O)OR, or SO₂R; R being H, C₁-C₂₀ alkyl, C₁-C₂₀ alkoxy, aryl, heteroaryl, C₃-C₂₀ cycloalkyl, or C₁-C₂₀ heterocycloalkyl. In certain implementations, each of R₁ and R₂, independently, is C₁-C₂₀ alkyl (e.g., 2-ethylhexyl).

In some implementations, the third comonomer repeat unit includes a cyclopentadithiophene moiety of formula (3):

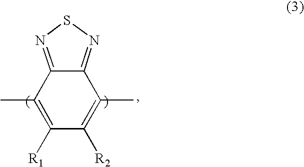

in which each of R₁ and R₂, independently, is H, C₁-C₂₀ alkyl, C₁-C₂₀ alkoxy, C₃-C₂₀ cycloalkyl, C₁-C₂₀ heterocycloalkyl, aryl, heteroaryl, halo, CN, OR, C(O)R, C(O)OR, or SO₂R; R being H, C₁-C₂₀ alkyl, C₁-C₂₀ alkoxy, aryl, heteroaryl, C₃-C₂₀ cycloalkyl, or C₁-C₂₀ heterocycloalkyl. In certain implementations, each of R₁ and R₂ is H.

Without wishing to be bound by theory, it is believed that incorporating a silacyclopentadithiophene moiety of formula (1) into a photoactive polymer could significantly improve the solubility and processibility of the polymer and the morphology of a photoactive layer 440 prepared from such a polymer, thereby increasing the efficiency of a photovoltaic cell. Further, without wishing to be bound theory, it is believed that incorporating a silacyclopentadithiophene moiety into a photoactive polymer can shift the absorption wavelength of the polymer toward the red and near IR portion (e.g., 650-800 nm) of the electromagnetic spectrum, which is not accessible by most other polymers. When such a co-polymer is incorporated into a photovoltaic cell, it enables the cell to absorb the light in this region of the spectrum, thereby increasing the current and efficiency of the cell. For example, replacing a photoactive polymer having co-monomer repeat units of formulas (2) and (3) with a photoactive polymer having co-monomer repeat units of formulas (1), (2), and (3) can increase the efficiency of a photovoltaic cell from about 3% to about 5% under the AM 1.5 conditions.

In general, the molar ratio of the comonomer repeat units in the polymer can vary as desired. In some implementations, the molar ratio of the first and second comonomer repeat units is at least about 1:1 (e.g., at least about 2:1, at least about 3:1, or at least 4:1) and/or at most about 6:1 (e.g., at most about 5:1, at most about 4:1, at most about 3:1, or at most about 2:1). Without wishing to be bound by theory, it is believed that, when the molar ratio of the first and second comonomer repeat units is above about 5:1, it can be difficult to process the resultant polymer to form a coating on a substrate, which can adversely affect the morphology of the photoactive polymer and lower the efficiency of a photovoltaic cell. Further, without wishing to be bound by theory, it is believed that, when the molar ratio of the first and second comonomer repeat units is less than about 1:1, a photovoltaic cell containing such a polymer may not have sufficient efficiency during operation.

An exemplary polymer that can be used in the photoactive layer 440 is

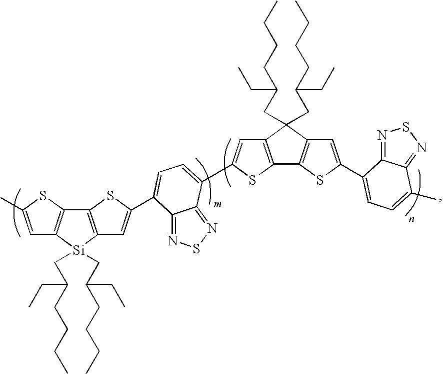

in which each of m and n, independently, is an integer greater than 1 (e.g., 2, 3, 5, 10, 20, 50, or 100). his polymer can have superior processibility and can be used to prepare a photovoltaic cell having an efficiency at least about 5% under AM 1.5 conditions.

Without wishing to be bound by theory, it is believed that a photovoltaic cell having a photoactive polymer containing the first, second, third comonomer repeat units described above can have a high efficiency. In some implementations, such a photovoltaic cell can have an efficiency of at least about 4% (e.g., at least about 5% or at least about 6%) under AM 1.5 conditions. Further, without wishing to be bound by theory, it is believed that other advantages of the polymers described above include suitable band gap (e.g., 1.4-1.6 eV) that can improve photocurrent and cell voltage, high positive charge mobility (e.g., 10⁻⁴ to 10⁻¹ cm² Vs) that can facilitate charge separation in photoactive layer 440, and high solubility in an organic solvent that can improve film forming ability and processibility. In some implementations, the polymers can be optically non-scattering.

The polymers described above can be prepared by methods known in the art. For example, a copolymer can be prepared by a cross-coupling reaction between one or more comonomers containing two organometallic groups (e.g., alkylstannyl groups, Grignard groups, or alkylzinc groups) and one or more comonomers containing two halo groups (e.g., Cl, Br, or I) in the presence of a transition metal catalyst. As another example, a copolymer can be prepared by a cross-coupling reaction between one or more comonomers containing two borate groups and one or more comonomers containing two halo groups (e.g., Cl, Br, or I) in the presence of a transition metal catalyst. Other methods that can be used to prepare the copolymers described above including Suzuki coupling reactions, Negishi coupling reactions, Kumada coupling reactions, and Stille coupling reactions, all of which are well known in the art.

The comonomers can be prepared by the methods described herein or by the methods know in the art, such as those described in U.S. patent application Ser. No. 11/486,536, Coppo et al., Macromolecules 2003, 36, 4705-2711 and Kurt et al., J. Heterocycl. Chem. 1970, 6, 629, the contents of which are hereby incorporated by reference. The comonomers can contain a non-aromatic double bond and one or more 10 asymmetric centers. Thus, they can occur as racemates and racemic mixtures, single enantiomers, individual diastereomers, diastereomeric mixtures, and cis- or trans-isomeric forms. All such isomeric forms are contemplated.

In some implementations, the photovoltaic cells used in telescoping device 1 can be tandem photovoltaic cells.

A tandem photovoltaic cell includes in general at least two semi-cells. In some implementations, the first semi-cell can include an electrode, an optional hole blocking layer, a first photoactive layer, and a recombination layer, and the second semi-cell can include a recombination layer, a second photoactive layer, a hole carrier layer, and an electrode. An external load is connected to photovoltaic cell via electrodes.

Depending on the production process and the desired device architecture, the current flow in a semi-cell can be reversed by changing the electron/hole conductivity of a certain layer (e.g., changing hole blocking layer to a hole carrier layer). By doing so, a tandem cell can be designed such that the semi-cells in the tandem cells can be electrically interconnected either in series or in parallel.

A recombination layer refers to a layer in a tandem cell where the electrons generated from a first semi-cell recombine with the holes generated from a second semi-cell. A recombination layer typically includes a p-type semiconductor material and an n-type semiconductor material. In general, n-type semiconductor materials selectively transport electrons and p-type semiconductor materials selectively transport holes. As a result, electrons generated from the first semi-cell recombine with holes generated from the second semi-cell at the interface of the n-type and p-type semiconductor materials.

In some implementations, the p-type semiconductor material includes a polymer and/or a metal oxide. Examples p-type semiconductor polymers include polythiophenes (e.g., poly(3,4-ethylene dioxythiophene) (PEDOT)), polyanilines, polyvinylcarbazoles, polyphenylenes, polyphenylvinylenes, polysilanes, polythienylenevinylenes, polyisothianaphthanenes, polycyclopentadithiophenes, polysilacyclopentadithiophenes, polycyclopentadithiazoles, polythiazolothiazoles, polythiazoles, polybenzothiadiazoles, poly(thiophene oxide)s, poly(cyclopentadithiophene oxide)s, polythiadiazoloquinoxaline, polybenzoisothiazole, polybenzothiazole, polythienothiophene, poly(thienothiophene oxide), polydithienothiophene, poly(dithienothiophene oxide)s, polytetrahydroisoindoles, and copolymers thereof. The metal oxide can be an intrinsic p-type semiconductor (e.g., copper oxides, strontium copper oxides, or strontium titanium oxides) or a metal oxide that forms a p-type semiconductor after doping with a dopant (e.g., p-doped zinc oxides or p-doped titanium oxides). Examples of dopants includes salts or acids of fluoride, chloride, bromide, and iodide. In some implementations, the metal oxide can be used in the form of nanoparticles.

In some implementations, the n-type semiconductor material (either an intrinsic or doped n-type semiconductor material) includes a metal oxide, such as titanium oxides, zinc oxides, tungsten oxides, molybdenum oxides, and combinations thereof. The metal oxide can be used in the form of nanoparticles. In other implementations, the n-type semiconductor material includes a material selected from the group consisting of fullerenes, inorganic nanoparticles, oxadiazoles, discotic liquid crystals, carbon nanorods, inorganic nanorods, polymers containing CN groups, polymers containing CF₃ groups, and combinations thereof.

In some implementations, the p-type and n-type semiconductor materials are blended into one layer. In certain implementations, the recombination layer includes two layers, one layer including the p-type semiconductor material and the other layer including the n-type semiconductor material. In such implementations, the recombination layer can include a layer of mixed n-type and p-type semiconductor materials at the interface of the two layers.

In some implementations, the recombination layer includes at least about 30 wt % (e.g., at least about 40 wt % or at least about 50 wt %) and/or at most about 70 wt % (e.g., at most about 60 wt % or at most about 50 wt %) of the p-type semiconductor material. In some implementations, the recombination layer includes at least about 30 wt % (e.g., at least about 40 wt % or at least about 50 wt %) and/or at most about 70 wt % (e.g., at most about 60 wt % or at most about 50 wt %) of the n-type semiconductor material.

The recombination layer generally has a sufficient thickness so that the layers underneath are protected from any solvent applied onto recombination layer. In some implementations, the recombination layer can have a thickness at least about 10 nm (e.g., at least about 20 nm, at least about 50 nm, or at least about 100 nm) and/or at most about 500 nm (e.g., at most about 200 mn, at most about 150 nm, or at most about 100 nm).

In general, the recombination layer is substantially transparent. For example, at the thickness used in a tandem photovoltaic cell, the recombination layer can transmit at least about 70% (e.g., at least about 75%, at least about 80%, at least about 85%, or at least about 90%) of incident light at a wavelength or a range of wavelengths (e.g., from about 350 nm to about 1,000 nm) used during operation of the photovoltaic cell.

The recombination layer generally has a sufficiently low surface resistance. In some implementations, the recombination layer has a surface resistance of at most about 1×10⁶ ohm/square (e.g., at most about 5×10⁵ ohm/square, at most about 2×10⁵ ohm/square, or at most about 1×10⁵ ohm/square).

Without wishing to be bound by theory, it is believed that the recombination layer can be considered as a common electrode between two semi-cells (e.g., one including a first electrode, a hole blocking layer, a first photoactive layer, and a recombination layer, and the other include the recombination layer, a second photoactive layer, a hole carrier layer, and a second electrode) in photovoltaic cells. In some implementations, the recombination layer can include an electrically conductive grid (e.g., mesh) material, such as those described above. An electrically conductive grid material can provide a selective contact of the same polarity (either p-type or n-type) to the semi-cells and provide a highly conductive but transparent layer to transport electrons to a load.

In some implementations, the recombination layer can be prepared by applying a blend of an n-type semiconductor material and a p-type semiconductor material on a photoactive layer. For example, an n-type semiconductor and a p-type semiconductor can be first dispersed and/or dissolved in a solvent together to form a dispersion or solution, which can then be coated on a photoactive layer to form a recombination layer.

In some implementations, a two-layer recombination layer can be prepared by applying a layer of an n-type semiconductor material and a layer of a p-type semiconductor material separately. For example, when titanium oxide nanoparticles are used as an n-type semiconductor material, a layer of titanium oxide nanoparticles can be formed by (1) dispersing a precursor (e.g., a titanium salt) in a solvent (e.g., an anhydrous alcohol) to form a dispersion, (2) coating the dispersion on a photoactive layer, (3) hydrolyzing the dispersion to form a titanium oxide layer, and (4) drying the titanium oxide layer. As another example, when a polymer (e.g., PEDOT) is used a p-type semiconductor, a polymer layer can be formed by first dissolving the polymer in a solvent (e.g., an anhydrous alcohol) to form a solution and then coating the solution on a photoactive layer.

Other components in a tandem cell can be formed of the same materials, or have the same characteristics, as those in the photovoltaic cell shown in FIG. 4.

Other examples of tandem photovoltaic cells have been described in, for example, commonly owned co-pending U.S. Application Publication Nos. 2007-0181179 and 2007-0246094, the entire contents of which are hereby incorporated by reference.

In some implementations, the semi-cells in a tandem cell are electrically interconnected in series. In certain implementations, the semi-cells in a tandem cell are electrically interconnected in parallel When interconnected in parallel, a tandem cell having two semi-cells can include the following layers: a first electrode, a first hole blocking layer, a first photoactive layer, a first hole carrier layer (which can serve as an electrode), a second hole carrier layer (which can serve as an electrode), a second photoactive layer, a second hole blocking layer, and a second electrode. In such implementations, the first and second hole carrier layers can be either two separate layers or can be one single layer. In case the conductivity of the first and second hole carrier layer is not sufficient, an additional layer (e.g., an electrically conductive mesh layer) providing the required conductivity may be inserted.

In some implementations, a tandem cell can include more than two semi-cells (e.g., three, four, five, six, seven, eight, nine, ten, or more semi-cells). In certain implementations, some semi-cells can be electrically interconnected in series and some semi-cells can be electrically interconnected in parallel.

In some implementations, the photovoltaic cell shown in FIG. 4 includes a cathode as a bottom electrode and an anode as a top electrode. In some implementations photovoltaic cell can also include an anode as a bottom electrode and a cathode as a top electrode.

In some implementations, a photovoltaic cell can include the layers shown in FIG. 4 in a reverse order. In other words, a photovoltaic cell can include these layers from the bottom to the top in the following sequence: a substrate 470, an electrode 460, a hole carrier layer 450, a photoactive layer 440, an optional hole blocking layer 430, an electrode 420, and a substrate 410.

In some implementations, multiple photovoltaic cells can be electrically connected to form a photovoltaic system. In some implementations, photovoltaic system can have a module containing photovoltaic cells. Cells are electrically connected in series, and system is electrically connected to a load. In some implementations, a photovoltaic system can have a module that contains photovoltaic cells. Cells are electrically connected in parallel, and system is electrically connected to a load. In some implementations, some (e.g., all) of the photovoltaic cells in a photovoltaic system can have one or more common substrates. In certain implementations, some photovoltaic cells in a photovoltaic system are electrically connected in series, and some of the photovoltaic cells in the photovoltaic system are electrically connected in parallel.

What is claimed is:

1. A device, comprising:
a first tube having a first slot and an inner diameter;
a first panel of photovoltaic cells in the first tube, at least a portion of the first panel being configured to be reversibly pulled in or out of the first tube through the first slot;
a second tube having a second slot and an outer diameter; and
a second panel of photovoltaic cells in the second tube, at least a portion of the second panel being configured to be reversibly pulled in or out of the second tube through the second slot;
wherein the outer diameter of the second tube is smaller than the inner diameter of the first tube and at least a portion of the second tube is inserted in the first tube.

2. The device of claim 1, wherein the entire first panel is configured to be reversibly pulled in or out of the first tube through the first slot and the entire second panel is configured to be reversibly pulled in or out of the second tube through the second slot.

3. The device of claim 1, further comprising
a first member attached to the first panel, the first member being configured to prevent separation of the first panel from the first tube when the first panel is pulled out of the first tube through the first slot; and
a second member attached to the second panel, the second member being configured to prevent separation of the second panel from the second tube when the second panel is pulled out of the second tube through the second slot.

4. The device of claim 3, wherein the first member is a first mandrel concentrically disposed in the first tube and the second member is a second mandrel concentrically disposed in the second tube.

5. The device of claim 4, wherein the first panel is rolled onto the first mandrel when the first panel is disposed in the first tube and the second panel is rolled onto the second mandrel when the second panel is disposed in the second tube.

6. The device of claim 1, wherein
the first tube further comprises:
a first opening of the first tube;
a second opening of the first tube; and
a cap of the first tube; and
the second tube further comprises:
a first opening of the second tube;
a second opening of the second tube; and
a cap of the second tube;
wherein the cap of the first tube is configured to cover the first opening of the first tube, the cap of the second tube is configured to cover the second opening of the second tube, and the first opening of the second tube is inserted into the first tube through the second opening of the first tube.

7. The device of claim 1, wherein the second tube is configured to be completely inserted into the first tube.

8. The device of claim 1, wherein the first panel is configured to be attached to the second panel when the first and second panels are respectively pulled out of the first and the second slots.

9. The device of claim 1,
wherein the first tube has an outer diameter and a length, the ratio between the outer diameter of the first tube and the length of the first tube being from about 1:2 to about 1:4.

10. The device of claim 1, wherein the first tube has an outer diameter of about 2.75 inches and a length of about 8.38 inches.

11. The device of claim 1, wherein the second tube is movable relative to the first tube.

12. The device of claim 1, wherein the first or second tube comprises plastic or metal.

13. The device of claim 1, wherein the first or second panel comprises photovoltaic cells having a photoactive layer that includes an organic electron donor material and an organic electron acceptor material.

14. The device of claim 13, wherein the organic electron donor material comprises a polymer selected from the group consisting of polythiophenes, polyanilines, polyvinylcarbazoles, polyphenylenes, polyphenylvinylenes, polysilanes, polythienylenevinylenes, polyisothianaphthanenes, polycyclopentadithiophenes, polysilacyclopentadithiophenes, polycyclopentadithiazoles, polythiazolothiazoles, polythiazoles, polybenzothiadiazoles, poly(thiophene oxide)s, poly(cyclopentadithiophene oxide)s, polythiadiazoloquinoxaline, polybenzoisothiazole, polybenzothiazole, polythienothiophene, poly(thienothiophene oxide), polydithienothiophene, poly(dithienothiophene oxide)s, polytetrahydroisoindoles, and copolymers thereof.

15. The device of claim 13, wherein the organic electron donor material comprises a polymer selected from the group consisting of polythiophenes, polycyclopentadithiophenes, and copolymers thereof.

16. The device of claim 13, wherein the organic electron donor material comprises poly(3-hexylthiophene) or poly(cyclopentadithiophene-co-benzothiadiazole).

17. The device of claim 13, wherein the organic electron acceptor material comprises a material selected from the group consisting of fullerenes, oxadiazoles, discotic liquid crystals, carbon nanorods, polymers containing CN groups, polymers containing CF₃ groups, and combinations thereof.

18. The device of claim 13, wherein the organic electron acceptor material comprises a substituted fullerene.

19. The device of claim 18, wherein the substituted fullerene comprises C61-PCBM or C71-PCBM.

20. A device, comprising:
a telescoping tube having a slot; and
a panel of photovoltaic cells in the telescoping tube, at least a portion of the panel being configured to be reversibly pulled in or out of the telescoping tube through the slot.

21. The device of claim 20, wherein the entire panel is configured to be reversibly pulled in or out of the tube through the slot.

22. The device of claim 20, further comprising a member attached to the panel of photovoltaic cells, the member being configured to prevent separation of the panel from the telescoping tube when the at least a portion of the panel is pulled out of the telescoping tube through the slot.

23. The device of claim 22, wherein the member is a mandrel concentrically disposed in the telescoping tube.

24. The device of claim 23, wherein the panel is rolled onto the mandrel when the panel is disposed in the telescoping tube.

25. The device of claim 20, wherein the telescoping tube further comprises a first opening, a second opening, a first cap configured to cover the first opening, and a second cap configured to cover the second opening.

26. The device of claim 20, wherein the at least a portion of the panel is configured to be split into at least two sub-panels when it is pulled out of the telescoping tube through the slot.

27. The device of claim 20, wherein the telescoping tube has a first length at a collapsed state and a second length at an extended state, the second length being larger than the first length.

28. The device of claim 27, the second length is at least about twice as large as the first length.

29. The device of claim 27, the second length is at least about three times as large as the first length.

30. The device of claim 27, wherein the telescoping tube has an outer diameter, the ratio between the outer diameter and the first length being from about 1:2 to about 1:4.

31. The device of claim 27, wherein the telescoping tube has an outer diameter of about 2.75 inches and a first length of about 8.38 inches.

32. The device of claim 20, wherein the telescoping tube comprises plastic or metal.

33. The device of claim 20, wherein the panel comprises photovoltaic cells having a photoactive layer that includes an organic electron donor material and an organic electron acceptor material.

34. The device of claim 33, wherein the organic electron donor material comprises a polymer selected from the group consisting of polythiophenes, polyanilines, polyvinylcarbazoles, polyphenylenes, polyphenylvinylenes, polysilanes, polythienylenevinylenes, polyisothianaphthanenes, polycyclopentadithiophenes, polysilacyclopentadithiophenes, polycyclopentadithiazoles, polythiazolothiazoles, polythiazoles, polybenzothiadiazoles, poly(thiophene oxide)s, poly(cyclopentadithiophene oxide)s, polythiadiazoloquinoxaline, polybenzoisothiazole, polybenzothiazole, polythienothiophene, poly(thienothiophene oxide), polydithienothiophene, poly(dithienothiophene oxide)s, polytetrahydroisoindoles, and copolymers thereof.

35. The device of claim 33, wherein the organic electron donor material comprises a polymer selected from the group consisting of polythiophenes, polycyclopentadithiophenes, and copolymers thereof.

36. The device of claim 33, wherein the organic electron donor material comprises poly(3-hexylthiophene) or poly(cyclopentadithiophene-co-benzothiadiazole).

37. The device of claim 33, wherein the organic electron acceptor material comprises a material selected from the group consisting of fullerenes, oxadiazoles, discotic liquid crystals, carbon nanorods, polymers containing CN groups, polymers containing CF₃ groups, and combinations thereof.

38. The device of claim 33, wherein the organic electron acceptor material comprises a substituted fullerene.

39. The device of claim 33, wherein the substituted fullerene comprises C61-PCBM or C71-PCBM.

40. A device, comprising a telescoping article and at least one photovoltaic cell in the telescoping article.

41. The device of claim 40, wherein the at least one photovoltaic cell is movable relative to the telescoping article.

42. The device of claim 40, wherein the at least one photovoltaic cell is part of a panel comprising a plurality of photovoltaic cells.

43. The device of claim 40, wherein the at least one photovoltaic cell is capable of being reversible pulled in or out of the telescoping article.
